(19) United States
(12) Patent Application Publication
(10) Pub. No.: US 2026/0271203 A1
(43) Pub. Date: Sep. 10, 2026

(54) HOUSING STRUCTURE

(71) Applicant: DENSO TEN Limited, Kobe (JP)

(72) Inventor: Katsunari FUKUI, Kobe (JP)

(73) Assignee: DENSO TEN Limited, Kobe (JP)

(21) Appl. No.: 19/560,273

(22) Filed: Mar. 9, 2026

(30) Foreign Application Priority Data
Mar. 10, 2025 (JP) 2025-037766

(51) Int. Cl. H05K 5/02; H05K 5/00

(52) U.S. Cl. CPC H05K 5/0247; H05K 5/0026

(57) ABSTRACT

A housing structure of a housing in which an antenna cord is disposed includes: a sheet metal chassis disposed in the housing; a flexible printed circuit disposed on a front surface side of the sheet metal chassis in the housing; a panel constituting a part of the housing and located on a back surface side of the sheet metal chassis; the antenna cord disposed between the sheet metal chassis and the flexible printed circuit in the housing so as to intersect with the flexible printed circuit; and a spacer protruding in a rib shape from a front surface of the panel and preventing contact between the flexible printed circuit and the antenna cord by securing a distance between the sheet metal chassis and the flexible printed circuit.

### CROSS-REFERENCE TO RELATED APPLICATIONS

This application is based upon and claims the benefit of priority from prior Japanese patent application No. 2025-37766, filed on March 10, 2025, the entire contents of which are incorporated herein by reference.

### TECHNICAL FIELD

The present disclosure relates to a housing structure in which an antenna cord is disposed.

### BACKGROUND ART

Various products including an antenna module have been known, for example, in-vehicle multimedia products such as a car navigation device and a display audio product mounted in a vehicle. An antenna cord, a flexible printed circuit (FPC), and the like are accommodated in a housing of the product including an antenna module.

### SUMMARY OF INVENTION

The antenna cord is formed by covering a conductive wire with an insulator, and has flexibility similar to the flexible printed circuit. In some cases, the antenna cord has to be laid out to intersect with the flexible printed circuit in the housing of the product. Depending on the degree of deflection of the antenna cord or the flexible printed circuit, the antenna cord and the flexible printed circuit may come into contact with each other. As a result, electro-magnetic compatibility (EMC) performance of the product may deteriorate. Such a problem tends to be remarkable in the case of an in-vehicle product that is easily affected by vehicle vibration or the like.

JP2004-328108A discloses an antenna attaching structure in which, when an antenna unit including a conductive member functioning as an antenna and a resin member covering the conductive member is disposed between a housing and a circuit board of a wireless device, the antenna unit is attached such that a structure formed of the resin member is crushed between the housing and the circuit board.

JP2004-328108A does not disclose a technique for preventing contact between the antenna cord and the flexible printed circuit in the housing of the device.

Aspects of the present disclosure relate to a technique of a housing structure in which an antenna cord is accommodated, and an object thereof is to provide a technique capable of preventing a deterioration in EMC performance of a product even in a case in which the antenna cord is disposed to intersect with a flexible printed circuit.

According to an aspect of the present disclosure, there is provided a housing structure of a housing in which an antenna cord is disposed, the housing structure including:

a sheet metal chassis disposed in the housing;

a flexible printed circuit disposed on a front surface side of the sheet metal chassis in the housing;

a panel constituting a part of the housing and located on a back surface side of the sheet metal chassis;

the antenna cord disposed between the sheet metal chassis and the flexible printed circuit in the housing so as to intersect with the flexible printed circuit; and

a spacer protruding in a rib shape from a front surface of the panel and preventing contact between the flexible printed circuit and the antenna cord by securing a distance between the sheet metal chassis and the flexible printed circuit.

According to aspects of the disclosure, a distance between a sheet metal chassis and the flexible printed circuit can be secured by a spacer protruding in a rib shape from an inner surface of a panel, and contact between the flexible printed circuit and the antenna cord can be prevented. Accordingly, it is possible to prevent the deterioration in the EMC performance of the product even in the case in which the antenna cord is disposed to intersect with the flexible printed circuit.

### BRIEF DESCRIPTION OF DRAWINGS

Exemplary embodiment(s) of the present invention will be described in detail based on the following figures, wherein:

FIG. 1 is a perspective view illustrating an example of a product to which a housing structure according to an embodiment is applied;

FIG. 2 is a rear view of the housing structure according to the embodiment;

FIG. 3 is a diagram schematically illustrating a cross-sectional view taken along a line B-B in a region surrounded by a broken line A in FIG. 2; and

FIG. 4 is a diagram illustrating a state in which spacers are inserted into openings provided in a sheet metal chassis.

### DESCRIPTION OF EMBODIMENTS

Hereinafter, an embodiment of the present disclosure will be described with reference to the drawings. Each of constituent elements, any combination thereof, and the like in the embodiment are examples, and additions, omissions, replacements, and other changes to the constituent elements can be made as appropriate without departing from the gist of the present disclosure.

### Embodiment

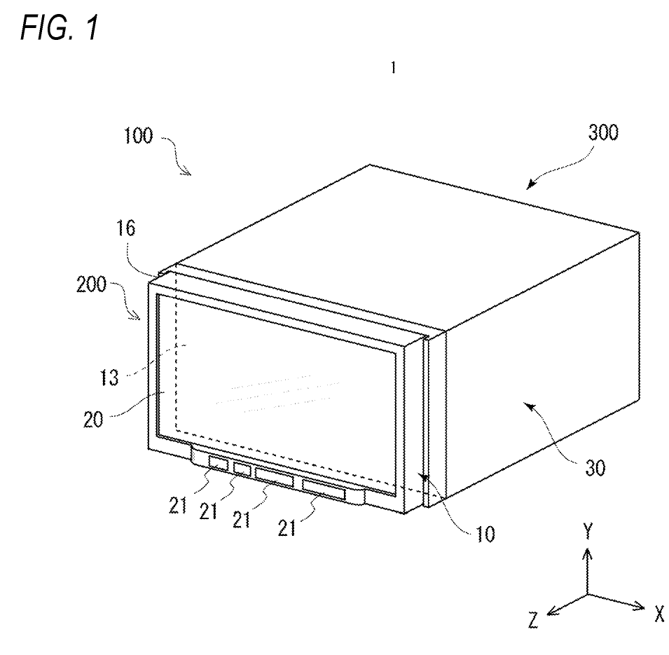

FIG. 1 is a perspective view illustrating an example of a product 100 to which a housing structure according to an embodiment is applied. The product 100 is an information device including an antenna module, and examples thereof include in-vehicle multimedia products such as a car navigation device and a display audio product. Here, the product 100 adopting the housing structure according to the present disclosure is described by taking a car navigation device as an example, but the product 100 capable of adopting the housing structure is not limited to an in-vehicle device.

In FIG. 1, the product 100 is, for example, a car navigation device in which a main body and a display are integrated, and has a car navigation function of performing route guidance to a current location or a destination of a vehicle, a reproduction function for various audio/visual (hereinafter referred to as AV) contents, a function of receiving broadcast waves, and the like. The product 100 may be, for example, a terminal cooperative navigation device that operates in cooperation with other terminal devices, for example, a personal computer (PC) and a mobile terminal such as a smartphone, by communicating with these terminal devices. Needless to say, the car navigation device as an example of the product 100 is not limited to the above configuration.

In the example illustrated in FIG. 1, the product 100 includes a display unit 200 and a main body unit 300. The display unit 200 includes a display housing 10 and a display 20 attached to the display housing 10. In the following description, a surface of the product 100 on which the display 20 is disposed is referred to as a "front surface" of the product 100. In a state in which the display 20 of the display unit 200 (product 100) is viewed in front elevation, a lateral direction (left-right direction) is represented as an X direction, and an up-down direction (vertical direction) is represented as a Y direction. The X direction and the Y direction are orthogonal to each other. Further, a depth direction of the display unit 200 (product 100) is represented as a Z direction. The depth direction (Z direction) of the display unit 200 (product 100) is orthogonal to both the lateral direction (X direction) and the up-down direction (Y direction).

The display 20 is, for example, a touch panel display (hereinafter, simply referred to as a "touch panel"), and is a graphical user interface (GUI) in which a color liquid crystal display and a touch sensor are combined, for example. In the example illustrated in FIG. 1, operation buttons 21 are disposed on a front surface side of the display unit 200. Each operation button 21 is, for example, a mechanical button (hard button). The display housing 10 is formed as, for example, a box-shaped housing (case) made of a resin, and accommodates various electronic components, a control board, and the like that constitute the display unit 200. The display housing 10 according to the present embodiment is an example of the housing according to the present disclosure. The shape of the display housing 10 illustrated in FIG. 1 is an example and is not particularly limited.

The main body unit 300 includes a main body unit housing 30. The main body unit housing 30 is formed as, for example, a box-shaped housing (case) made of a metal, and accommodates various electronic components, a control board, and the like that constitute the main body unit 300. The shape of the main body unit housing 30 illustrated in FIG. 1 is an example and is not particularly limited.

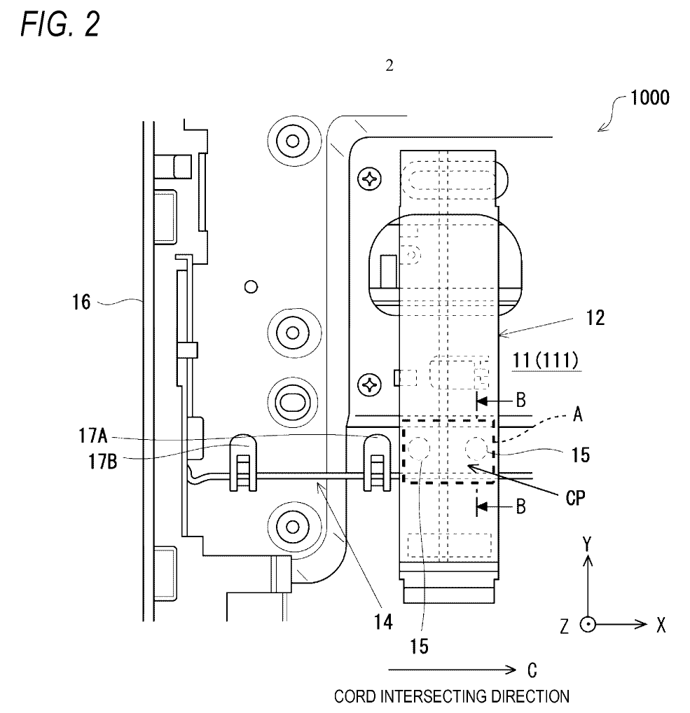

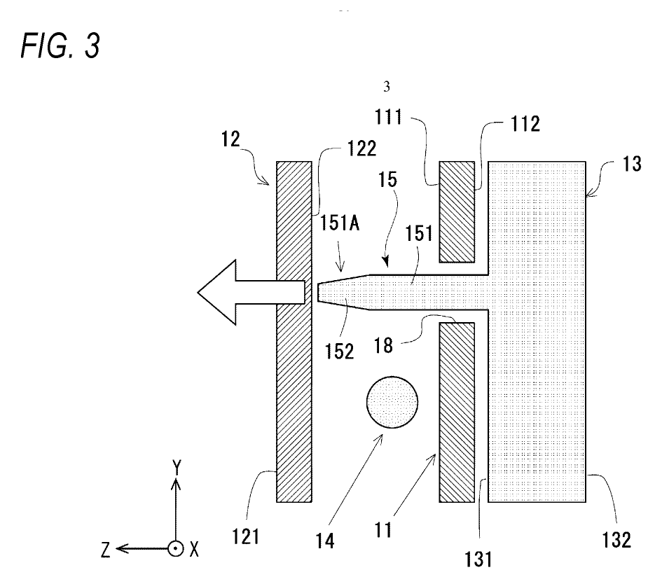

FIG. 2 is a view illustrating an internal structure of the display housing 10. FIG. 2 is a cross-sectional view of the display housing 10 in the XY plane, and illustrates an internal structure of a part of the display housing 10. In FIG. 2, the inside of the display housing 10 is viewed from the front surface side (display 20 side). FIG. 3 is a diagram schematically illustrating a cross-sectional view taken along a line B-B in a region surrounded by a broken line A in FIG. 2.

A housing structure (internal structure) 1000 according to the display housing 10 includes

a sheet metal chassis 11 that is disposed in the display housing 10,

a flexible printed circuit 12 that is disposed on a front surface side of the sheet metal chassis 11 in the display housing 10,

a back-surface panel 13 that constitutes a part of the display housing 10 and is located on a back surface side of the sheet metal chassis 11,

an antenna cord 14 that is disposed between the sheet metal chassis 11 and the flexible printed circuit 12 in the display housing 10 so as to intersect with the flexible printed circuit 12, and

spacers 15 each of which is made of a resin, protrudes in a rib shape from a front surface of the back-surface panel 13, and prevents contact between the flexible printed circuit 12 and the antenna cord 14 by securing a distance between the sheet metal chassis 11 and the flexible printed circuit 12.

In FIG. 1, FIG. 2, or FIG. 3, the reference numeral 16 denotes a side panel of the display housing 10. The reference numeral 111 denotes a front surface of the sheet metal chassis 11, and the reference numeral 112 denotes a back surface of the sheet metal chassis 11.

The back-surface panel 13 is, for example, a panel disposed on a back surface side of the display unit 200, and is located at a boundary with the main body unit housing 30 provided on the back surface side of the display unit 200. The reference numeral 131 illustrated in FIG. 3 denotes the front surface of the back-surface panel 13. The front surface 131 of the back-surface panel 13 is an inner surface facing the inside of the display housing 10. The back-surface panel 13 is an example of the panel according to the present disclosure.

The sheet metal chassis 11 is disposed on the front surface side of the back-surface panel 13 to face the back-surface panel 13. In other words, the back-surface panel 13 in the display housing 10 is disposed on the back surface side of the sheet metal chassis 11 disposed in the display housing 10. For example, the sheet metal chassis 11 has a panel shape, and the sheet metal chassis 11 and the back-surface panel 13 extend along the XY plane. As illustrated in FIG. 3, the front surface 131 of the back-surface panel 13 and the back surface 112 of the sheet metal chassis 11 are disposed to face each other. The sheet metal chassis 11 is disposed to enhance the strength of the display housing 10 and to improve the electromagnetic wave shielding property, for example.

The flexible printed circuit 12 is disposed on the front surface side of the sheet metal chassis 11 in the display housing 10. The flexible printed circuit 12 (FPC) is also called a flexible board, and is a thin and flexible substrate. The flexible printed circuit 12 has a structure in which, for example, a base film (for example, polyimide) serving as a thin film-like insulator is used and an adhesive layer and a conductor foil are laminated onto the base film. The flexible printed circuit 12 functions as, for example, a cable that connects rigid substrates or units of the product 100. As an example, the flexible printed circuit 12 is connected to a display substrate disposed in the display housing 10 and a main body unit substrate disposed in the main body unit housing 30 via a connector and the like. In FIG. 3, the reference numeral 121 denotes a front surface of the flexible printed circuit 12, and the reference numeral 122 denotes a back surface of the flexible printed circuit 12. As illustrated in FIG. 3, the back surface 122 of the flexible printed circuit 12 is set to face the front surface 111 of the sheet metal chassis 11, and is disposed in a state of being separated from the front surface 111 of the sheet metal chassis 11.

Next, the antenna cord 14 will be described. For example, one end of the antenna cord 14 is connected to an antenna in the antenna module, and the other end thereof is connected to the main body unit substrate disposed in the main body unit housing 30. The antenna cord 14 is a flexible cord (cable) in which a conductive wire is covered with an insulator. As illustrated in FIG. 2, a part of the antenna cord 14 is wired along the front surface side of the sheet metal chassis 11. In the example illustrated in FIG. 2, the antenna cord 14 is clamped by holders 17A and 17B such as clips provided on the front surface 111 of the sheet metal chassis 11, and is fixed along the front surface side of the sheet metal chassis 11 via the holders 17A and 17B. For example, the antenna cord 14 is wired along the front surface 111 to be in contact with the front surface 111 of the sheet metal chassis 11. In the example illustrated in FIG. 2, the two holders 17A and 17B are provided at an interval along a planned wiring position of the antenna cord 14, but positions, the number, and the like of the holders 17A and 17B are not particularly limited. Further, a method for fixing the antenna cord 14 by the holders 17A and 17B is not limited to the above clamping method.

The antenna cord 14 disposed in the display housing 10 may have to be laid out to intersect with the flexible printed circuit 12 as illustrated in FIG. 2. According to the aspect illustrated in FIG. 2, the antenna cord 14 is disposed to be inserted between the sheet metal chassis 11 and the flexible printed circuit 12 at a position where the antenna cord 14 and the flexible printed circuit 12 intersect with each other. As described above, the flexible printed circuit 12 and the antenna cord 14 have flexibility. Therefore, in a case in which the flexible printed circuit 12 or the antenna cord 14 is bent or a case in which the flexible printed circuit 12 and the antenna cord 14 are shaken due to vehicle vibration or the like, when the antenna cord 14 and the flexible printed circuit 12 come into contact with each other, there is a possibility that electro-magnetic compatibility (EMC) performance of the product 100 deteriorates. Therefore, the housing structure 1000 according to the present disclosure adopts a structure for preventing the EMC performance of the product 100 from deteriorating even when the antenna cord 14 is disposed to intersect with the flexible printed circuit 12.

Specifically, the housing structure 1000 includes the resin spacers 15 that prevent the contact between the flexible printed circuit 12 and the antenna cord 14 by securing the distance between the sheet metal chassis 11 and the flexible printed circuit 12. As illustrated in FIG. 3, the spacers 15 protrude forward (toward the sheet metal chassis 11) from the front surface 131 of the back-surface panel 13 in the rib shape. The back-surface panel 13 of the display housing 10 according to the present embodiment is made of a resin, and is integrally molded with the spacers 15, for example.

The resin spacers 15 have a pin shape (also referred to as a shaft shape or a rod shape). As an example, each spacer 15 has a shaft portion 151 that protrudes in a columnar shape from the front surface 131 of the back-surface panel 13, and a chamfered portion 152 having a chamfered shape is formed at a tip portion 151A of the shaft portion 151. Further, as an example, the sheet metal chassis 11 has openings 18 through which the spacers 15 can be inserted toward the flexible printed circuit 12. By providing the openings 18 in the sheet metal chassis 11, the spacers 15 protruding from the back-surface panel 13 can be brought into contact with the back surface 122 of the flexible printed circuit 12 through the openings 18, and the flexible printed circuit 12 can be pushed up by the tip portions 151A of the spacers 15.

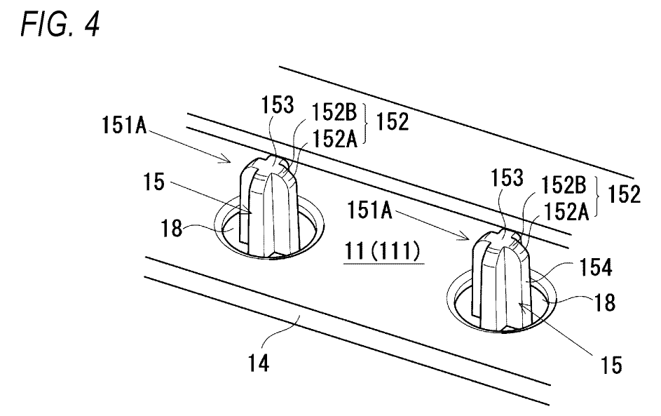

FIG. 4 is a diagram illustrating a state in which the spacers 15 are inserted into the openings 18 provided in the sheet metal chassis 11. In addition, an arrow C illustrated in FIG. 2 indicates a cord intersecting direction in which the antenna cord 14 intersects with the flexible printed circuit 12. In the example illustrated in FIG. 2, the two spacers 15 are disposed at an intersecting portion CP where the antenna cord 14 intersects with the flexible printed circuit 12. The two spacers 15 are disposed at an interval along the cord intersecting direction C at the intersecting portion CP. Each spacer 15 pushes up the flexible printed circuit 12 by abutting the tip portion 151A against the back surface 122 of the flexible printed circuit 12. Accordingly, it is possible to prevent the flexible printed circuit 12 from excessively approaching the sheet metal chassis 11. As a result, the distance between the sheet metal chassis 11 and the flexible printed circuit 12 can be suitably secured, and the contact between the flexible printed circuit 12 and the antenna cord 14 disposed along the front surface 111 of the sheet metal chassis 11 can be prevented. Therefore, it is possible to prevent the EMC performance of the product 100 from deteriorating.

Further, according to the housing structure 1000 of the present embodiment, since surface contact between the sheet metal chassis 11 and the flexible printed circuit 12 can be avoided, it is possible to more suitably prevent the deterioration of the EMC performance in the product 100. In the present embodiment, the antenna cord 14 is disposed along the front surface 111 of the sheet metal chassis 11. Therefore, the contact between the antenna cord 14 and the flexible printed circuit 12 can be suitably prevented by using the spacers 15 to suitably secure the distance between the sheet metal chassis 11 and the flexible printed circuit 12. In particular, by using the holders 17A and 17B or the like to fix the antenna cord 14 along the front surface 111 of the sheet metal chassis 11, it is possible to prevent the antenna cord 14 from being bent or the antenna cord 14 from being excessively separated from the sheet metal chassis 11. As a result, the contact between the antenna cord 14 and the flexible printed circuit 12 can be further suitably prevented.

Further, according to the housing structure 1000 of the present embodiment, it is not necessary to lay out the antenna cord 14 to bypass the flexible printed circuit 12 in order to avoid the intersection of the antenna cord 14 with the flexible printed circuit 12. Therefore, the degree of freedom of the wiring layout of the antenna cord 14 is improved. In addition, since the wiring length of the antenna cord 14 can be shortened, cost reduction can be achieved. Further, since the spacers 15 that push up the flexible printed circuit 12 are made of a resin, it is possible to prevent the flexible printed circuit 12 from being damaged or scratched. Further, in the present embodiment, since the resin back-surface panel 13 and the spacers 15 are integrally molded, the number of parts can be reduced, which can contribute to the cost reduction.

In the present embodiment, the resin spacers 15 protruding from the back-surface panel 13 are inserted into the openings 18 formed in the sheet metal chassis 11, and then the flexible printed circuit 12 is pushed up by the spacers 15. In this regard, according to the present embodiment, an opening area of the opening 18 formed in the sheet metal chassis 11 can be reduced by forming the resin spacer 15 in the pin shape. As a result, it is possible to further suitably prevent the deterioration of the EMC performance in the product 100.

In addition, in the present embodiment, the spacer 15 may be configured to secure a separation distance between the sheet metal chassis 11 and the flexible printed circuit 12 to be larger than a diameter of the antenna cord 14. Accordingly, it is possible to more reliably prevent the contact between the flexible printed circuit 12 and the antenna cord 14 wired along the sheet metal chassis 11, and thus it is possible to more reliably prevent the deterioration of the EMC performance in the product 100.

In the example illustrated in FIG. 4, the opening 18 formed in the sheet metal chassis 11 has a hole shape penetrating the sheet metal chassis 11, and an edge portion is formed around the entire circumference of the hole, but a notch shape may be adopted instead of the hole shape. That is, the opening 18 may be formed by a notch formed in the sheet metal chassis 11.

Further, in the example illustrated in FIG. 4, the chamfered portion 152 having the chamfered shape is formed at the tip portion 151A of the spacer 15. In FIG. 4, the reference numeral 153 denotes a top surface of the spacer 15, and the reference numeral 154 denotes a side surface of the spacer 15. The side surface 154 of the spacer 15 extends, for example, parallel to an axial direction in which the shaft portion 151 of the spacer 15 extends, and the top surface 153 extends in a direction orthogonal to the axial direction of the shaft portion 151. In the example illustrated in FIG. 4, the chamfered portion 152, which is chamfered to connect an upper end of the side surface 154 and the top surface 153 of the spacer 15, is provided. For example, the chamfered portion 152 may include a C-chamfered portion 152A and an R-chamfered portion 152B that are continuously provided in the up-down direction, the C-chamfered portion 152A may be disposed on a side surface 154 side, and the R-chamfered portion 152B may be disposed on a top surface 153 side. C-chamfering is a chamfering process of obliquely cutting a corner portion. R-chamfering is a chamfering process of rounding a corner portion.

By forming the chamfered portion 152 having the chamfered shape at the tip portion 151A of the spacer 15, the antenna cord 14 is less likely to be sandwiched between the tip portions 151A of the spacers 15 and the flexible printed circuit 12 when the back-surface panel 13 is fitted into the side panel 16 during manufacturing and assembling of the display unit 200. That is, even when the antenna cord 14 is located on an extension of the spacers 15 during a fitting operation of the back-surface panel 13, the antenna cord 14 easily slides down on surfaces of the chamfered portions 152. Accordingly, it is possible to prevent the antenna cord 14 from being placed on the spacers 15. Needless to say, the above-described aspect of the chamfered portion 152 is an example, and the chamfered portion 152 may include any one of the C-chamfered portion 152A and the R-chamfered portion 152B. Further, the chamfered portion 152 may not be formed in the tip portion 151A of the spacer 15.

Although the embodiment according to the present disclosure has been described above, the aspects disclosed in the present specification can be combined.

What is claimed is:

1. A housing structure of a housing in which an antenna cord is disposed, the housing structure comprising:
a sheet metal chassis disposed in the housing;
a flexible printed circuit disposed on a front surface side of the sheet metal chassis in the housing;
a panel constituting a part of the housing and located on a back surface side of the sheet metal chassis;
the antenna cord disposed between the sheet metal chassis and the flexible printed circuit in the housing so as to intersect with the flexible printed circuit; and
a spacer protruding in a rib shape from a front surface of the panel and preventing contact between the flexible printed circuit and the antenna cord by securing a distance between the sheet metal chassis and the flexible printed circuit.

2. The housing structure according to claim 1, wherein
the sheet metal chassis has an opening through which the spacer is able to be inserted toward the flexible printed circuit.

3. The housing structure according to claim 1, wherein
the spacer has a pin shape.

4. The housing structure according to claim 1, wherein
a tip end of the spacer has a chamfered shape.

5. The housing structure according to claim 1, wherein
the antenna cord is disposed along the front surface side of the sheet metal chassis.

6. The housing structure according to claim 5, wherein
the antenna cord is fixed along the front surface side of the sheet metal chassis.

7. The housing structure according to claim 1, wherein
the spacer ensures a separation distance between the sheet metal chassis and the flexible printed circuit to be larger than a diameter of the antenna cord.

8. The housing structure according to claim 1, wherein
the panel is made of a resin and is integrally molded with the spacer.
